(19) United States
(12) Patent Application Publication
(10) Pub. No.: US 2010/0147386 A1
(43) Pub. Date: Jun. 17, 2010

(54) Doped interfacial modification layers for stability enhancement for bulk heterojunction organic solar cells

(75) Inventors: Jessica Benson-smith, Pittsburgh, PA (US); Christohper T. Brown, Pittsburgh, PA (US); Shijun Jia, Cheswick, PA (US); Darin W. Laird, Pittsburgh, PA (US); Christine L. McGuiness, Pittsburgh, PA (US); Bal Mukund Dhar, Baltimore, MD (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 12/591,509

(22) Filed: Nov. 20, 2009

Related U.S. Application Data
(60) Provisional application No. 61/116,963, filed on Nov. 21, 2008.

(51) Int. Cl. H01L 31/0256

(52) U.S. Cl. 136/263

(57) ABSTRACT

Organic photovoltaic (OPV) devices comprising an organic semiconductor doped with a metal or organic dopant to form an interfacial modification layer, where the layer is disposed on an active layer including a conjugated polymer and a fullerene are described. In the layer, the organic semiconductor can be BPhen or TPBI, and the dopant can be a metal or an organic material. In the active layer, the conjugated polymer can be P3HT and the fullerene can be PCBM or indenyl-substituted fullerene. Improved OPV efficiency and lifetime can be achieved. Good testing results are obtained despite high humidity and high temperature, and modules can be made.

### RELATED APPLICATIONS

This application claims priority to U.S. provisional application Ser. No. 61/116,963 filed Nov. 21, 2008, which is hereby incorporated by reference in its entirety.

### BACKGROUND

A need exists to provide more efficient organic photovoltaic (“OPV”) devices with longer lifetimes. This is driven in part by ongoing high fuel prices and unstable fuel supply. OPV devices can provide improvements over older silicon devices. See, for example, Perlin, John “The Silicon Solar Cell Turns 50” NREL 2004; see also, Dennler et al., “Flexible Conjugated Polymer-Based Plastic Solar Cells: From Basics to Applications,” Proceedings of the IEEE, vol. 93, no. 8, August 2005, 1429-1439. Global climate change is also a motivating factor.

### SUMMARY

Solar cell devices are described herein with particular importance being attributed to the compositions of an interfacial modification layer and an active layer, as well as methods of making and using same.

For example, one embodiment provides a device comprising: at least one anode; at least one organic photovoltaic device active layer disposed on the anode, wherein the active layer comprises at least one p-type material and one n-type material; at least one interfacial modification layer disposed on the active layer, wherein the interfacial modification layer comprises at least one dopant and at least one organic semiconductor; and at least one cathode disposed on the interfacial modification layer, wherein the dopant and the active layer are adapted to provide the device with a power conversion efficiency of at least 4%.

Another embodiment provides a device comprising: at least one anode, at least one organic photovoltaic device active layer disposed on the anode, wherein the active layer comprises at least one conjugated polymer and at least one fullerene, wherein the fullerene comprises an indenyl-substituted fullerene, at least one interfacial modification layer disposed on the active layer, wherein the interfacial modification layer comprises at least one metal, which is an inner transition metal, and at least one organic semiconductor, and at least one cathode disposed on the interfacial modification layer.

Another embodiment provides a device comprising: at least one anode, at least one organic photovoltaic device active layer disposed on the anode, wherein the active layer comprises at least one p-type material and at least one n-type material, at least one interfacial modification layer disposed on the active layer, wherein the interfacial modification layer comprises at least one dopant and at least one organic semiconductor, and at least one cathode disposed on the interfacial modification layer, wherein the dopant and the active layer are adapted to provide the device with a lifetime that is at least about 25% longer than an analogous device that does not contain the interfacial modification layer.

Another embodiment is a device comprising: at least one anode; at least one organic photovoltaic device active layer disposed on the anode, wherein the active layer comprises at least one conjugated polymer and at least one fullerene, wherein the fullerene comprises an indenyl-substituted fullerene, at least one interfacial modification layer disposed on the active layer, wherein the interfacial modification layer comprises at least one metal, which is an inner transition metal, and at least one organic semiconductor, and at least one cathode disposed on the interfacial modification layer, wherein the metal and the fullerene are adapted to provide the device with a power conversion efficiency of at least 4%.

Other embodiments comprise methods of making and using these embodiments, as well as compositions and substructures of these embodiments, including coated substrates, for example. Other embodiments include modules which are devices comprising solar cell or organic photovoltaic devices. The modules can generate electrical power and currents.

Additional embodiments include, for example:

A device comprising: at least one substrate; at least one anode disposed on the substrate; at least one organic photovoltaic device active layer disposed on the anode, wherein the active layer comprises at least one p-type material and one n-type material; at least one optical spacer layer disposed on the active layer, wherein the optical spacer layer comprises at least one dopant and at least one organic semiconductor; and at least one cathode disposed on the optical spacer layer, wherein the dopant and the active layer are adapted to provide the device with a power conversion efficiency of at least 4%. The interfacial modification layer can be in many embodiments also an optical spacer layer.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the p-type material comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the n-type material is selected from the group consisting of [6,6]-phenyl-C₆₁-butyric acid methyl ester (PCBM) and indenyl-substituted fullerenes. In one embodiment, the p-type material comprises P3HT and the n-type material is selected from the group consisting of PCBM and indenyl-substituted fullerenes. In one embodiment, the p-type material and n-type material of the active layer are present in a ratio of from about 1 n-type to about 1 to about 2 p-type, based on weight. In one embodiment, the dopant comprises a metal. In one embodiment, the dopant is selected from the group consisting of alkali metals, alkali earth metals, transition metals, rare earth metals, and metal oxides. In one embodiment, the dopant is selected from the group consisting of cesium, barium, magnesium, molybdenum oxide, tungsten oxide, chromium, silver, gold, lithium, calcium, and ytterbium. In one embodiment, the dopant comprises an organic material. In one embodiment, the dopant is selected from the group consisting of TTF, Pyronin B, BEDT-TTF, and cobaltocene. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % dopant. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprising a hole transport layer, and wherein the substrate is transparent, the anode comprises indium tin oxide, the active layer comprises P3HT and indenyl-derivitized fullerene, the optical spacer comprises BPhen and ytterbium, and the cathode comprises aluminum.

Another embodiment provides a device comprising: at least one substrate, at least one anode disposed on the substrate, at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the conjugated polymer comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the fullerene is selected from the group consisting of [6,6]-phenyl-C₆₁-butyric acid methyl ester (PCBM) and indenyl-substituted fullerenes. In one embodiment, the conjugated polymer comprises P3HT and the fullerene is selected from the group consisting of PCBM and indenyl-substituted fullerenes. In one embodiment, the conjugated polymer and fullerene are present in a ratio of from about 1 conjugated polymer to about 1 to about 2 fullerenes, based on weight. In one embodiment, the optical spacer layer metal comprises ytterbium. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % metal. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, wherein the substrate is transparent, the anode comprises indium tin oxide, the active layer comprises P3HT and indenyl-substituted fullerene, the optical spacer comprises BPhen and ytterbium, and the cathode comprises aluminum. In one embodiment, the optical spacer layer organic semiconductor has a HOMO value lower in energy than the HOMO value of the active layer conjugated polymer.

Another embodiment provides a device comprising: at least one substrate, at least one anode disposed on the substrate, at least one organic photovoltaic device active layer disposed on the anode, wherein the active layer comprises at least one p-type material and at least one n-type material, at least one optical spacer layer disposed on the active layer, wherein the optical spacer layer comprises at least one dopant and at least one organic semiconductor, and at least one cathode disposed on the optical spacer layer, wherein the dopant and the active layer are adapted to provide the device with a lifetime that is at least about 25% longer than an analogous device that does not contain the optical spacer.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the p-type material comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the n-type material is selected from the group consisting of [6,6]-phenyl-C₆₁-butyric acid methyl ester (PCBM) and indenyl-substituted fullerenes. In one embodiment, the p-type material comprises P3HT and the n-type material is selected from the group consisting of PCBM and indenyl-substituted fullerenes. In one embodiment, the p-type material and n-type material of the active layer are present in a ratio of from about 1 n-type to about 1 to about 2 p-type, based on weight. In one embodiment, the dopant comprises a metal. In one embodiment, the dopant is selected from the group consisting of alkali metals, alkali earth metals, transition metals, rare earth metals, and metal oxides. In one embodiment, the dopant is selected from the group consisting of cesium, barium, magnesium, molybdenum oxide, tungsten oxide, chromium, silver, gold, lithium, calcium, and ytterbium. In one embodiment, In one embodiment, the dopant comprises an organic material. In one embodiment, the dopant is selected from the group consisting of TTF, Pyronin B, BEDT-TTF, and cobaltocene. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % dopant. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, wherein the substrate is transparent, the anode comprises indium tin oxide, the active layer comprises P3HT and indenyl-substituted fullerene, the optical spacer comprises BPhen and ytterbium, and the cathode comprises aluminum.

Another embodiment provides a device comprising: at least one substrate, at least one anode disposed on the substrate, at least one organic photovoltaic device active layer disposed on the anode, wherein the active layer comprises at least one conjugated polymer and at least one indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a lifetime that is at least about 25% longer than an analogous device that does not contain the optical spacer.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the conjugated polymer comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the fullerene is selected from the group consisting of [6,6]-phenyl-C₆₁-butyric acid methyl ester (PCBM) and indenyl-substituted fullerenes. In one embodiment, the conjugated polymer comprises P3HT and the fullerene is selected from the group consisting of PCBM and indenyl-substituted fullerenes. In one embodiment, the conjugated polymer and fullerene are present in a ratio of from about 1 conjugated polymer to about 1 to about 2 fullerenes, based on weight. In one embodiment, the optical spacer layer metal comprises ytterbium. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % metal. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, wherein the substrate is transparent, the anode comprises indium tin oxide, the active layer comprises P3HT and indenyl-substituted fullerene, the optical spacer comprises BPhen and ytterbium, and the cathode comprises aluminum. In one embodiment, the optical spacer layer organic semiconductor has a HOMO value lower in energy than the HOMO value of the active layer conjugated polymer.

Another embodiment provides a device comprising: at least one substrate; at least one anode disposed on the substrate; at least one organic photovoltaic device active layer disposed on the anode, wherein the active layer comprises at least one p-type material and one n-type material; at least one optical spacer layer disposed on the active layer, wherein the optical spacer layer comprises at least one dopant and at least one organic semiconductor; and at least one cathode disposed on the optical spacer layer, wherein the dopant and the active layer are adapted to provide the device with a normalized power output greater that about 80% of initial power for at least about 25 hours.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the p-type material comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the n-type material is selected from the group consisting of [6,6]-phenyl-C₆₁-butyric acid methyl ester (PCBM) and indenyl-substituted fullerenes. In one embodiment, the p-type material comprises P3HT and the n-type material is selected from the group consisting of PCBM and indenyl-substituted fullerenes. In one embodiment, the p-type material and n-type material of the active layer are present in a ratio of from about 1 n-type to about 1 to about 2 p-type, based on weight. In one embodiment, the dopant comprises a metal. In one embodiment, the dopant is selected from the group consisting of alkali metals, alkali earth metals, transition metals, rare earth metals, and metal oxides. In one embodiment, the dopant is selected from the group consisting of cesium, barium, magnesium, molybdenum oxide, tungsten oxide, chromium, silver, gold, lithium, calcium, and ytterbium. In one embodiment, the dopant comprises an organic material. In one embodiment, the dopant is selected from the group consisting of TIT, Pyronin B, BEDT-TTF, and cobaltocene. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % dopant. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, wherein the substrate is transparent, the anode comprises indium tin oxide, the active layer comprises P3HT and indenyl-substituted fullerene, the optical spacer comprises BPhen and ytterbium, and the cathode comprises aluminum.

Another embodiment provides a device comprising: at least one substrate, at least one anode disposed on the substrate; at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a power conversion efficiency of at least 4%.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment, the conjugated polymer comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof. In one embodiment, the fullerene is selected from the group consisting of [6,6]-phenyl-C₆₁-butyric acid methyl ester (PCBM) and indenyl-substituted fullerenes. In one embodiment, the conjugated polymer comprises P3HT and the fullerene is selected from the group consisting of PCBM and indenyl-substituted fullerenes. In one embodiment, the conjugated polymer and fullerene are present in a ratio of from about 1 conjugated polymer to about 1 to about 2 fullerenes, based on weight. In one embodiment, the optical spacer layer metal comprises ytterbium. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % metal. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, wherein the substrate is transparent, the anode comprises indium tin oxide, the active layer comprises P3HT and indenyl-substituted fullerene, the optical spacer comprises BPhen and ytterbium, and the cathode comprises aluminum. In one embodiment, the optical spacer layer organic semiconductor has a HOMO value lower in energy than the HOMO value of the active layer conjugated polymer.

Another embodiment provides a device comprising: at least one substrate, at least one anode disposed on the substrate; at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a normalized power output greater that about 80% of initial power for at least about 25 hours.

In one embodiment, the substrate is transparent. In one embodiment, the anode comprises a transparent conductor. In one embodiment, the anode comprises a transparent conductive metal-metal oxide. In one embodiment, the anode comprises indium tin oxide, SnO, ZnO, or NiO₍ₓ₎.TiO₂. In one embodiment, the device further comprises a hole transport layer between the anode and the active layer. In one embodiment, the hole transport layer comprises a semi-conducting organic polymer. In one embodiment, the semi-conducting organic polymer comprises PEDOT:PSS, regioregular polythiophene, 3-,4-alkoxysubstituted polythiophene, sulfonated polythiophene, arylaminobenzene materials, polyarylaminoketones, or combination thereof. In one embodiment,

the conjugated polymer comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, copolymer comprising at least one dithieno[3,2-b:2′,3′-d]pyrrole (DTP) repeat unit, or mixtures thereof. In one embodiment, the fullerene is selected from the group consisting of [6,6]-phenyl-C₆₁-butyric acid methyl ester (PCBM) and indenyl-substituted fullerenes. In one embodiment, the conjugated polymer comprises P3HT and the fullerene is selected from the group consisting of PCBM and indenyl-substituted fullerenes. In one embodiment, the conjugated polymer and fullerene are present in a ratio of from about 1 conjugated polymer to about 1 to about 2 fullerenes, based on weight. In one embodiment, the optical spacer layer metal comprises ytterbium. In one embodiment, the organic semiconductor is selected from the group consisting of Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups. In one embodiment, the optical spacer layer comprises ytterbium and BPhen. In one embodiment, the optical spacer layer comprises about 5 wt. % to about 30 wt. % metal. In one embodiment, the optical spacer layer is about 1 nm to about 30 nm thick. In one embodiment, the active layer is about 150 nm to about 250 nm thick. In one embodiment, the cathode comprises aluminum. In one embodiment, the device further comprises a hole transport layer, and wherein the substrate is transparent, the anode comprises indium tin oxide, the active layer comprises P3HT and indenyl-substituted fullerene, the optical spacer comprises BPhen and ytterbium, and the cathode comprises aluminum. In one embodiment, the optical spacer layer organic semiconductor has a HOMO value lower in energy than the HOMO value of the active layer conjugated polymer.

Another embodiment provides a method of using a device comprising: obtaining the device comprising: at least one substrate; at least one anode disposed on the substrate; at least one organic photovoltaic device active layer disposed on the anode, wherein the active layer comprises at least one p-type material and one n-type material; at least one optical spacer layer disposed on the active layer, wherein the optical spacer layer comprises at least one dopant and at least one organic semiconductor; and at least one cathode disposed on the optical spacer layer, wherein the dopant and the active layer are adapted to provide the device with a power conversion efficiency of at least 4%, and exposing the device to light.

Another embodiment provides a method of using a device comprising: obtaining the device comprising: at least one substrate, at least one anode disposed on the substrate, at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, and exposing the device to light.

Another embodiment provides a method of using a device comprising: obtaining the device comprising: at least one substrate, at least one anode disposed on the substrate, at least one organic photovoltaic device active layer disposed on the anode, wherein the active layer comprises at least one p-type material and at least one n-type material, at least one optical spacer layer disposed on the active layer, wherein the optical spacer layer comprises at least one dopant and at least one organic semiconductor, and at least one cathode disposed on the optical spacer layer, wherein the dopant and the active layer are adapted to provide the device with a lifetime that is at least about 25% longer than an analogous device that does not contain the optical spacer, and exposing the device to light.

Another embodiment provides a method of using a device comprising: obtaining the device comprising: at least one substrate, at least one anode disposed on the substrate, at least one organic photovoltaic device active layer disposed on the anode, wherein the active layer comprises at least one conjugated polymer and at least one indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a lifetime that is at least about 25% longer than an analogous device that does not contain the optical spacer, and exposing the device to light.

Another embodiment provides a method of using a device comprising: obtaining the device comprising: at least one substrate; at least one anode disposed on the substrate; at least one organic photovoltaic device active layer disposed on the anode, wherein the active layer comprises at least one p-type material and one n-type material; at least one optical spacer layer disposed on the active layer, wherein the optical spacer layer comprises at least one dopant and at least one organic semiconductor; and at least one cathode disposed on the optical spacer layer, wherein the dopant and the active layer are adapted to provide the device with a normalized power output greater that about 80% of initial power for at least about 25 hours, and exposing the device to light.

Another embodiment provides a method of using a device comprising: obtaining the device comprising: at least one substrate, at least one anode disposed on the substrate; at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a power conversion efficiency of at least 4%, and exposing the device to light.

Another embodiment provides a method of using a device comprising: obtaining the device comprising: at least one substrate, at least one anode disposed on the substrate; at least one organic photovoltaic device active layer disposed on the anode, wherein the active layer comprises at least one conjugated polymer and at least one fullerene, wherein the fullerene comprises an indenyl-substituted fullerene, at least one optical spacer layer disposed on the active layer, wherein the optical spacer layer comprises at least one metal, which is an inner transition metal, and at least one organic semiconductor, and at least one cathode disposed on the optical spacer layer, wherein the metal and the fullerene are adapted to provide the device with a normalized power output greater that about 80% of initial power for at least about 25 hours, and exposing the device to light.

Another embodiment provides a device comprising: at least one substrate; at least one anode disposed on the substrate; at least one organic photovoltaic device active layer disposed on the anode, wherein the active layer comprises at least one p-type material and one n-type material; at least one spacer layer disposed on the active layer, wherein the spacer layer comprises at least one dopant and at least one organic semiconductor; and at least one cathode disposed on the layer, wherein the dopant and the active layer are adapted to provide the device with a power conversion efficiency of at least 4%.

The devices described herein can be adapted to other OPV device structures including, for example, inverted solar cell devices.

Also provided are methods for assembling the devices as described herein. The elements of the device can be provided and then assembled by methods known in the art.

In at least one embodiment, at least one advantage is excellent efficiency including power conversion efficiency.

In at least one embodiment, at least one advantage is excellent lifetime and stability, including testing under harsh humidity, temperature, and time conditions.

In at least one embodiment, at least one advantage is excellent efficiency including power conversion efficiency combined with excellent lifetime and stability.

### BRIEF DESCRIPTION OF THE DRAWINGS

FIG. 1 shows a schematic of one embodiment of a solar cell device of the present application.

FIG. 2 shows device lifetime data for A) a solar cell device without an interfacial modification layer, and B) a solar cell device including an interfacial modification layer of the present application.

FIG. 3 shows structures of molecules that can be included in the interfacial modification layer of devices of the present application.

FIG. 4A shows burn-in data for OPV modules containing Li:BPhen, Yb:BPhen, and Yb:TBPI in the OS and PV2000 in the active layer, evaluated under conditions of 85° C./85% R.H. with 0.4 Sun Xe lamp intensity (“QSun”) and ambient conditions with 1 Sun Xe lamp intensity.

FIG. 4B shows burn-in data for OPV modules containing Li:BPhen, Yb:BPhen, and Yb:TBPI in the OS and PV1000 in the active layer, evaluated under conditions of 85° C./85% R.H. with 0.4 Sun Xe lamp intensity (“QSun”) and ambient conditions with 1 Sun Xe lamp intensity.

FIG. 5 shows burn-in data for OPV modules containing Ca and Li:BPhen in the OS and PV1000 and PV2000 in the active layer, evaluated under conditions of 85° C./85% R.H. with 0.4 Sun Xe lamp intensity (“QSun”) and ambient conditions with 1 Sun Xe lamp intensity.

FIG. 6A. shows a TEM image of an OPV module active layer (with P3HT), Ca layer, and Al layer.

FIG. 6B. shows XPS depth profiles of the Al, Ca, and carbon layers of the module of FIG. 6A.

FIG. 6C. shows XPS depth profiles for various sulfur moieties in the active layer of the module of FIG. 6A.

FIG. 7A. shows a TEM image of an OPV module active layer (with P3HT), Yb:BPhen layer, and Al layer.

FIG. 7B. shows XPS depth profiles of the Al, Yb:BPhen, and carbon layers of the module of FIG. 7A.

FIG. 7C. shows XPS depth profiles for various sulfur moieties in the active layer of the module of FIG. 7A.

FIG. 8 shows the modules of Example 6.

### DETAILED DESCRIPTION

### Introduction

All references cited herein are hereby incorporated by reference in their entireties.

The present application has a variety of embodiments but generally relates to the use of an organic semiconductor doped with a metal or organic material to form an interfacial modification layer (IML). In some cases, at least, the IML also could be called or function as an optical spacer (“OS”) layer, where the IML or OS is disposed on an active layer including a p-type material and an n-type material. An OS is an IML when the OS is at the interface. For example, an electron transport layer (“ETL”), including an organic semiconductor, such as, for example, TPBI or 4,7-diphenyl-1,10-phenanthroline (“BPhen”) doped with a metal, e.g. TPBI:Yb, or BPhen:Li, or BPhen:Yb etc., when disposed between the active layer and the cathode of a device, such as a bulk heterojunction solar cell or small molecule solar cell, can effectively increase the absorption in the active layer of the device, thereby improving device efficiency. See, for example, Chan et al. (2006) APL, 89, 163515; and Colsmann et al., Proceedings of SPIE, Organic optoelectronics and photonics, (2006), vol. 6192, pp. 619220.1-619220.

When a layer X is disposed on an object such as another layer, the layer X can be directly contacting the object, or an intermediate material can be disposed between the layer X and the object.

### Organic Photovoltaic Devices (“OPVs”)

A photovoltaic cell can be an electrochemical device that converts electromagnetic radiation to electrical energy. OPVs, also known as organic solar cells, are described in, for example, U.S. Provisional Patent Application No. 61/090,464 and U.S. Non-Provisional patent application Ser. No. 11/743,587 (Plextronics), both of which are hereby incorporated by reference in their entirety. Various architectures for OPVs are known; elements typically include electrodes, e.g., an anode and a cathode, an active layer, and a substrate to support the larger structure. So-called inverted devices can be made. In addition to these elements, an HTL, interfacial modification, or optical spacer layer, and one or more conditioning layers may also be used in an OPV.

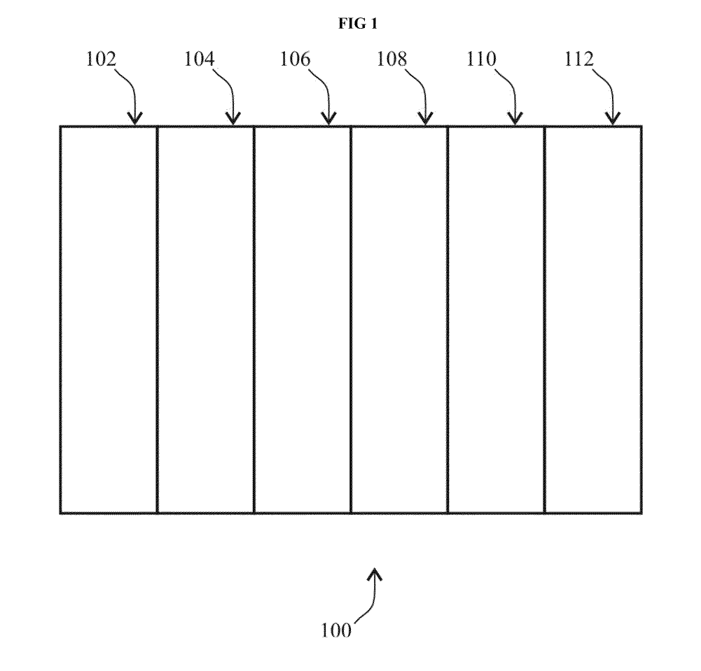

An example of a solar cell device is shown in FIG. 1. As known in the art, the value of such a device is that it may be used to directly convert solar radiation into usable energy without the generation of chemical waste products or a dependence on petroleum- or coal-based energy. This “clean” and renewable energy can be used to charge batteries or operate electronic devices. It offers advantages to electrical applications which are electrically driven by an electrical distribution grid, either as a replacement for a battery or as means to restore the charge on a battery which is then used to power a device. Finally, it can be used to supplement power supply on the electrical distribution grid or to replace power supply from the electrical distribution grid.

### Electrodes

Electrodes, including anodes and cathodes, are known in the art for photovoltaic devices, and known electrode materials can be used to fabricate electrodes in embodiments of the present application. For example, transparent conductive oxide, metal-metal oxide, sulfide material, metal, and combinations of metals can be used. Transparency can be adapted for a particular application. The anode may commonly comprise metals, such as, for example, gold, silver, and the like, carbon nanotubes (single or multiwalled), transparent conducting oxides such as, for example, indium tin oxide (“ITO”), SnO, ZnO, and NiO₍ₓ₎.TiO₂, and transparent conducting oxides such as, for example, ITO, SnO, ZnO, and NiO₍ₓ₎.TiO₂ comprising additional metal components. Desirably, the anode can be ITO including ITO supported on a substrate. Substrates can be rigid or flexible. The substrate can be, for example, glass, quartz, plastics such as, for example, PTFE, polysiloxanes, thermoplastics such as, for example, PET, PEN, and the like, metals such as, for example, aluminum, gold, and silver, metal foils, metal oxides, such as, for example, TiOx and ZnOx, and semiconductors, such as, for example, silicon. The cathode may desirably comprise a metal, such as, for example, aluminum, calcium, or mixtures of aluminum and calcium.

### Active Layer

Between the electrodes are either discrete layers or a mixture of p- and n-type semiconductors, which together constitute the “active layer” of the OPV. The p-type material can be called the primary light harvesting component or layer. This material absorbs a photon of a particular energy and generates a state in which an electron is promoted to an excited energy state, leaving a positive charge or “hole” in the ground state energy levels. As known in the art, this is called exciton formation. The exciton diffuses to a junction between p-type and n-type material, creating a charge separation or dissociation of the exciton. The electron and “hole” charges are conducted through the n-type and p-type materials respectively to the electrodes, resulting in the flow of electric current out of the OPV.

The p-type material can be an organic material including a polymeric material, although other types of p-type material are known in the art. For example, the p-type material can comprise a conjugated polymer or a conducting polymer comprising a polymer backbone having a series of conjugated double bonds. The p-type material can be, for example, a homopolymer or a copolymer, including a block copolymer, a random copolymer, or a terpolymer. Examples of p-type materials include polythiophene, polypyrrole, polyaniline, polyfluorene, polyphenylene, polyphenylene vinylene, and derivatives, copolymers, and mixtures thereof. The p-type material can comprise, for example, a conjugated polymer soluble or dispersible in organic solvent or water. The p-type semiconductor can comprise conjugated polymers including, for example, including poly-phenylenevinylene (“PPV”) poly (3-hexyl)thiophene (“P3HT”), substituted polythiophenes, substituted polycarbazoles, copolymer comprising at least one dithieno[3,2-b:2′,3′-d]pyrrole (DTP) repeat unit, or mixtures or blends of these materials. Low band gap and donor acceptor polymers can be used as p-type materials. For materials comprising DTP and related components, see, for example, U.S. provisional application 61/029,255 filed Feb. 15, 2008.

The n-type component can comprise materials with a strong electron affinity including, for example, carbon fullerenes, such as, for example, indenyl-substituted fullerenes, titanium dioxide, cadmium selenium, polymers, and small molecules that are specifically designed to exhibit n-type behavior. The n-type material may commonly include fullerene derivatives, such as, for example, those described in U.S. Non-Provisional application Ser. No. 11/743,587, which is hereby incorporated by reference in its entirety.

In some embodiments of the present application, the active layers comprise commercially available inks, such as, for example, PV2000 and PV1000 (Plextronics, Pittsburgh, Pa.). The aforementioned inks are typically formulated from a mixture of n-type and p-type materials, and are commonly dissolved in an organic solvent, such as, for example, dichlorobenzene, chlorobenzene, toluene, xylenes, and blends of solvents such as, for example, toluene/xylene, nitrobenzene/toluene, etc. The n- and p-type materials can be mixed in a ratio of, for example, from about 0.1 to 4.0 (p-type) to about 1 (n-type) based on a weight, from about 1.1 to about 3.0 (p-type) to about 1 (n-type), or from about 1 to about 1.5 (p-type) to about 1 (n-type). The amount of each type of material or the ratio between the two types of components can be varied for the particular application. Total solids for formulations for active layers of the present application are commonly about 1 wt. % to about 3 wt. %.

### Hole Transport Layer

Photovoltaic cells can optionally include a hole transport layer (“HTL”), where the HTL is disposed between the anode and the active layer. The optional HTL can be added using, for example, spin casting, ink jetting, doctor blading, spray casting, dip coating, vapor depositing, or any other known deposition method. The HTL can be, for example, PEDOT, PEDOT/PSS or TBD, or NPB, or Plexcore OC (Plextronics, Pittsburgh, Pa.).

### Interfacial Modification Layer (“IML”)

One layer can be a spacer layer or an interfacial modification layer. The interfacial modification layer can comprise at least one material that is an organic, semiconducting compound, and at least one dopant which can be an organic compound or an alkali metal, alkali earth metal, rare earth metal, or metal oxide.

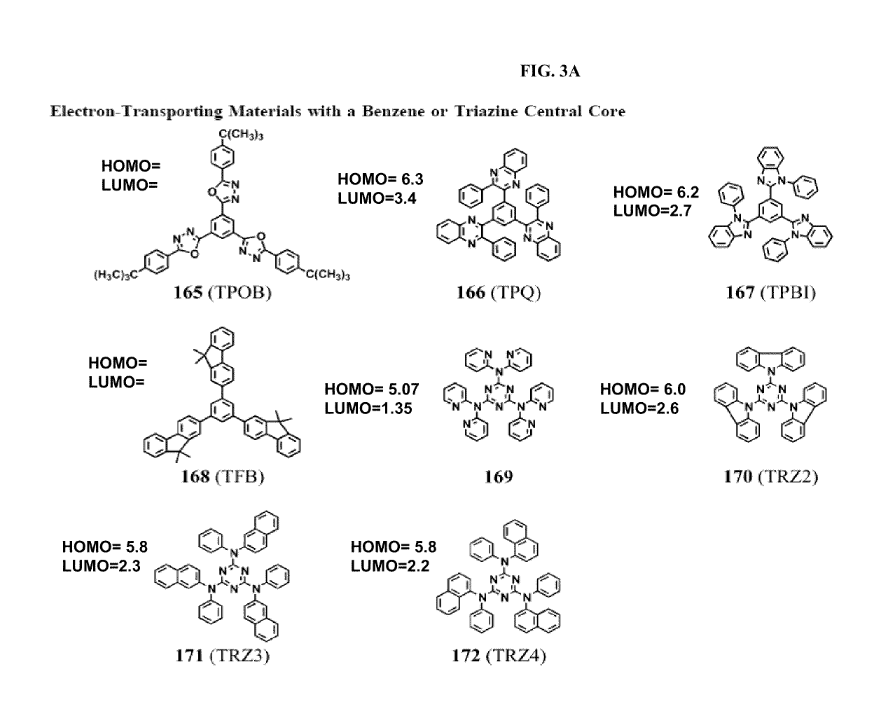

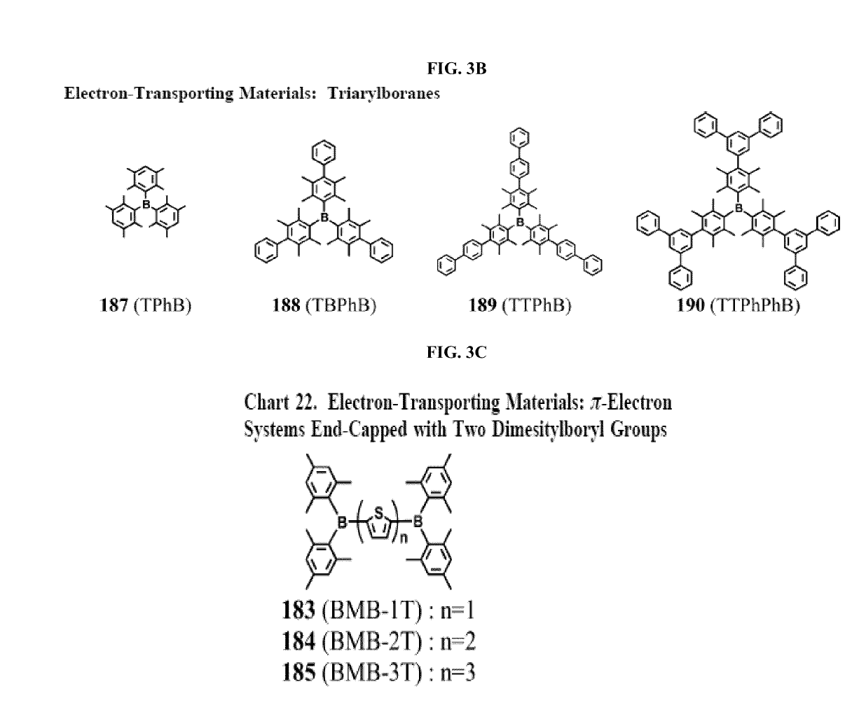

The organic semiconductor material of the present application is desirably hole blocking, meaning that, although not limited by theory, it can have a HOMO value lower in energy than that of the HOMO of the hole transporting material in the OPV active layer. For example, if the active layer comprises P3HT, the HOMO of the organic material in the IML can be approximately −5.2 eV or less. Examples of organic semiconductor materials suitable for the OS layer of the present application include, for example, Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), 1,3,5-tris(2-N-phenylbenzimidazolyl) benzene (“TPBI”), 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, triarylboranes such as, for example, TPhB, TPPhB, TTPhB, and TTPhPhB, and thiophene-based molecules capped with two dimesitylboryl groups, as shown in FIG. 3. Metals that can be suitable dopants for the organic semiconductor can include, for example, alkali metals, alkali earth metals, transition metals, rare earth metals, and metal oxides. Particularly suitable dopant metals and metal oxides may include, for example, cesium, barium, magnesium, molybdenum, cobalt, molybdenum oxide, tungsten oxide, chromium, silver, gold, lithium, calcium, and ytterbium. Organic materials that can be suitable dopants can include, for example, TTF, Pyronin B, BEDT-TTF, and cobaltocene. Commonly the metal or organic dopant can be about 1 wt. % to about 60 wt. % of the IML, about 2 wt. % to about 50 wt. % of the IML, about 3 wt. % to about 40 wt. % of the IML, about 4 wt. % to about 30 wt. % of the IML, about 5 wt. % to about 20 wt. % of the IML, or about 6 wt. % to about 10 wt. % of the IML. Commonly the IML may be about 1 nm to about 100 nm thick, about 1 nm to about 60 nm thick, about 3 nm to about 30 nm thick, about 5 nm to about 20 nm thick, or about 10 nm to about 15 nm thick.

### Adapted to Provide

The dopant and the active layer can be adapted to provide the device with properties such as, for example, power conversion efficiency or lifetime, or combinations thereof. For example, one can select the chemical or elemental composition, and/or one can select the amount of the components. One can select combinations of materials and amounts until the properties can be achieved. For the active layer, one can select the identity and amounts of the n-type and p-type materials. One can, if desired, consider electronic energy levels including HOMO and LUMO calculations and measurements. One can in some cases also adapt the preparation methods. One can take measurements to determine if the properties are achieved or not, and adapt accordingly based on the results.

### Device Preparation:

Devices of the present application can be made according known methods in the art. FIG. 1 shows a schematic of one embodiments of a solar cell device (100) of the present application, including a substrate (102), anode (104), hole transport layer (106), active layer (108), interfacial modification layer (IML) or optical spacer layer (110), and cathode (112). For example, the devices can be made using ITO as an anode material on a substrate. Other anode materials can include, for example, metals such as Au, carbon nanotubes (single or multiwalled), and other transparent conducting oxides. The resistivity of the anode can be maintained below, for example, 15 Ω/sq or less, 25 or less, 50 or less, or 100 or less, or 200 or less, or 250 or less. The substrate can be for example glass, plastics (PTFE, polysiloxanes, thermoplastics, PET, PEN and the like), metals (Al, Au, Ag), metal foils, metal oxides, (TiOx, ZnOx) and semiconductors, such as Si. The ITO on the substrate can be cleaned using techniques known in the art prior to device layer deposition.

Inverted devices can be also made as known in the art. Modules can be prepared comprising a plurality of OPV devices.

An optional hole transport layer (“HTL”) can be deposited on the anode using, for example, spin casting, ink jetting, doctor blading, spray casting, dip coating, vapor depositing, or any other known deposition method. The HTL can be for example PEDOT, PEDOT/PSS or TBD, or NPB, or Plexcore HTL (Plextronics, Pittsburgh, Pa.), or materials described in, for example, US Patent publication 2008/0248313 published Oct. 9, 2008; provisional applications Ser. Nos. 61/044,380 filed Apr. 11, 2008; 61/108,851 filed Oct. 27, 2008; and 61/115,877 filed Nov. 18, 2008 (all assigned to Plextronics).

The thickness of the HTL layer can be, for example, from about 10 nm to about 300 nm thick, from 30 nm to 60 nm thick, from 60 nm to 100 nm thick, or from 100 nm to 200 nm thick. The HTL layer can be optionally dried/annealed at 110 to 200° C. for about 1 min to about an hour, optionally in an inert atmosphere. Methods for annealing are known in the art.

The active layer can be formulated from a mixture of n-type and p-type materials. The n- and p-type materials can be mixed in a ratio of for example from about 0.1 to 4.0 (p-type) to about 1 (n-type) based on a weight, or from about 1.1 to about 3.0 (p-type) to about 1 (n-type) or from about 1 to about 1.2 (p-type) to about 1 (n-type). The amount of each type of material or the ratio between the two types of components can be varied for the particular application. In some embodiments, the active layer may comprise commercially-available inks, such as, for example, PV2000 and PV1000 (Plextronics, Pittsburgh, Pa.). The active layer can be deposited by spin casting, slot die coating, ink jetting, doctor blading, spray casting, dip coating, vapor depositing, or any other known deposition method, on top of the anode, if no HTL is present, or on top of the HTL, if an HTL is present. The active layer film can be optionally annealed at about 40° C. to about 250° C., or from about 150° C. to about 180° C., for about one minute to two hours, or for about 10 minutes to about an hour, in an inert atmosphere. In some embodiments, the active layer can further comprise additional ingredients including, for example, surfactants, dispersants, and oxygen and water scavengers. In some embodiments, the active layer can comprise multiple layers or be multi-layered.

An IML may be included between the active layer and the cathode. Typically the IML deposition comprises the co-evaporation of two materials at a base pressure of about 7×10⁻⁷ mbar, such as, for example, BPhen and a metal dopant, e.g., calcium, lithium, ytterbium etc., or BPhen and an organic dopant, e.g., TTF, Pyronin B, BEDT-TTF etc. These materials are commonly deposited such that the final OS film has a metal dopant or organic dopant concentration of about 1 to 40 wt. %, about 5 to 30 wt. %, or about 10 to 20 wt. %. The IML can be, for example, from about 0.5 nm to about 100 nm, from about 0.75 nm to about 60 nm, or from about 1 nm to about 30 nm, thick.

Next, a cathode layer can be added to the device, generally using, for example, thermal evaporation of one or more metals. For example, a 10 to 300 nm Al layer can be thermally evaporated onto the IML. The devices can be then encapsulated using a glass cover slip sealed with a UV curable glue, or other epoxy or plastic coatings. Cavity glass with a getter/desiccant may also be used.

### OPV Parameters/Efficiency

Performance of OPVs can be determined by measurement of the efficiency of conversion of light energy to electrochemical energy as measured by the quantum efficiency (number of photons effectively used divided by the number of photons absorbed) and by the peak output power generated by the cell (given by the product IppVpp where Ipp is the current and Vpp is the voltage at peak power).

Known solar cell parameters can be measured including, for example, Jsc (mA/cm²) and Voc (V) and fill factor (FF) and power conversion efficiency (%, PCE) by methods known in the art. The OPV efficiency can be at least about 4%, or at least about 4.3%, or at least about 4.7%, or at least about 5%, or at least about 5.3%, or at least about 6.0%, or at least about 6.7%, at 1 sun (AM1.5G, 100 mW/cm²). An efficiency range can be for example about 4% to about 8%, or about 4.3% to about 6.7%, or about 5% to about 6.3%. These efficiencies can be verified by, for example, NREL, Fraunhoffer, or other such certification center.

The fill factor, for example, can be at least about 0.55, or at least about 0.60, or at least about 0.65, at least about 0.7, at least about 0.75, at least about 0.8, or at least about 0.85.

The Voc (V), for example, can be at least about 0.56, or at least about 0.63, or at least about 0.82, or at least about 0.9, or at least about 1.0, or at least about 1.2, or at least about 1.4, or at least about 1.5.

The Jsc (mA/cm²), for example, can be at least about 8, or at least about 9.2, or at least about 9.48, or at least about 10, or at least about 11, or at least about 12, or at least about 13, or at least about 14, or at least about 15.

Oriel Solar Simulators can be used to determine OPV properties including for example FF, Jsc, Voc, and efficiencies. The simulator can be calibrated by methods known in the art including for example calibration with a KG5-Si reference cell.

### OPV Lifetime

A Xenon lamp (Atlas Specialty Lighting, PE240E-13FM) can be used to generate both the temperature and light. The output designation of ‘1Suns’ is derived from adjusting the intensity of light falling on the devices to be such that a KG-5 cell placed in the same fixture would generate the same current it generates under standard AM 1.5G testing. The devices can be connected to a data acquisition setup where an adjustable DC load maintains them at their maximum power point (“MPP”). The power output of the cells may be continuously monitored over time. In addition, intermittent monitoring of the PV parameters such as Voc, FF, Jsc may also be performed. Currently OPV lifetime is defined as the amount of time that an OPV device or module diminishes to 80% of its ‘stabilized’ power output (or power conversion efficiency) normalized by the illumination intensity (lamp variation or decay) under ˜1 Sun Xe-arc Lamp with (or converted to) 50% duty cycle.

In one embodiment of the present application, the lifetime of the device that includes an IML at least removes “burn-in” decay that analogous devices without the OS layer usually have, and is at least about 25% longer than an analogous device that does not contain the IML. In other embodiments, the lifetime of the device that includes an IML can be at least about 10% longer, 20% longer, 25% longer, 30% longer, 35% longer, 40% longer, 50% longer, 60% longer, 70% longer, 100% longer, 200% longer, or 500% longer than an analogous device that does not contain the IML. In other embodiments, the normalized power output of a device prepared according to the present application may be greater than about 80% of initial power for at least about 10 hours, 20 hours, 30 hours, 40 hours, 50 hours, 60 hours, 70 hours, 80 hours, 90 hours, 100 hours, 250 hours, 500 hours, 750 hours, 1,000 hours, 2,500 hours, 5,000 hours, 7,500 hours, or 10,000 hours than an analogous device that does not contain the IML.

Another important aspect is the combination of good efficiency and long lifetime, particularly long lifetime under rigorous testing conditions of high humidity and high temperature.

### WORKING EXAMPLES

Various claimed embodiments are described further with use of non-limiting working examples.

### Example 1

### Fabrication of Solar Cell Device Using PV1000 and PV2000 Inks and BPhen Doped with Lithium

Indium tin oxide (“ITO”) coated substrates were purchased from Thin Film Devices (“TFD”, Anaheim, Calif.). These substrates were cleaned in a Class 10,000 clean room by sonicating for 20 min in a soap solution, followed by 20 min of sonication in water, 20 min of sonication in acetone and 20 min of sonication in IPA. Finally the substrates were exposed to UV ozone (300 W) for 10 min. After cleaning, each substrate was then coated with an about 30 nm thick layer of Baytron AI4083 (H.C Stark) by spin coating for 5 seconds at 400 rpm in air, followed by a 1 minute at 6000 rpm. The devices were then annealed on a hot plate at 175° C. for 30 min in a N₂ atmosphere glove box.

The substrates were then transferred to a dry-box for continued processing. The active layer was then spin-coated on top of the HTL layer using one of the two following ink formulations: PV 2000 or PV 1000. These inks were spin cast onto the substrate for 3 min spin at 350 rpm in a nitrogen atmosphere and resulted in films with thicknesses of ˜200-250 nm. The devices were then annealed on a hot plate at 175° C. for 30 min in a nitrogen atmosphere. Finally, after annealing, the cathode or the IML followed by the cathode was vapor deposited from a base pressure of ˜7×10⁻⁷. An IML comprising an electron transporting material such as BPhen, TPBI, or BCP (Sigma) and a metal (Li, Yb, or Ca, purchased from Kurt Lesker) were thermally evaporated on the surface of the solar cell device active layer inside a high vacuum chamber (˜7×10⁻⁷−10⁻⁶ mbar) to form a layer (about 3-20 nm) comprising about 10-20 wt. % metal. The rate of deposition of the electron transport material was about 1 A/s. The rate of deposition of the metal ranged from 0.1 A/s to 0.6 A/s. Finally, an aluminum cathode layer (200 nm) was deposited on the IML. The device was then encapsulated via a glass cover slip (blanket) encapsulation sealed with EPO-TEK OG112-4 UV curable glue. The encapsulated device was cured under UV irradiation (80 mW/cm²) for 4 minutes and tested as follows.

The photovoltaic characteristics of devices under white light exposure (Air Mass 1.5 Global Filter) were measured using a system equipped with a Keithley 2400 source meter and an Oriel 300 W Solar Simulator based on a Xe lamp with output intensity of 100 mW/cm² (AM1.5G). The light intensity was set using an NREL-certified Si-KG5 silicon photodiode.

### Example 2

### Power Conversion Efficiency Determinations

Devices were prepared as described in Example 1 above were tested using an Oriel Solar Simulator and the voltage was swept from reverse to forward bias. From the resulting current that was measured, the power conversion efficiency of each device was determined. Data for each device are summarized in Table 1.

TABLE 1
Measured OPV Device Parameters

| Run | Active | OS | Jsc | Voc | | Efficiency |
|---|---|---|---|---|---|---|
| Number | Layer | Layer | (mA/cm²) | (V) | FF | (%) |
| 1 | PV2000 | BPhen: Yb | 10.05 | 0.85 | 0.70 | 5.94 |
| 2 | PV2000 | BPhen: Li | 1.59 | 0.53 | 0.34 | 0.28 |
| 3 | PV2000 | BPhen: Ca | 9.5 | 0.78 | 0.30 | 2.14 |
| 4 | PV2000 | None | 10.05 | 0.84 | 0.66 | 5.69 |
| 1 | PV1000 | BPhen: Yb | 10.65 | 0.61 | 0.65 | 4.22 |
| 2 | PV1000 | BPhen: Li | 7.89 | 0.56 | 0.59 | 2.58 |
| 3 | PV1000 | BPhen: Ca | 8.54 | 0.58 | 0.25 | 1.23 |
| 4 | PV1000 | None | 10.2 | 0.58 | 0.51 | 3.06 |

### Example 3

### Lifetime Testing

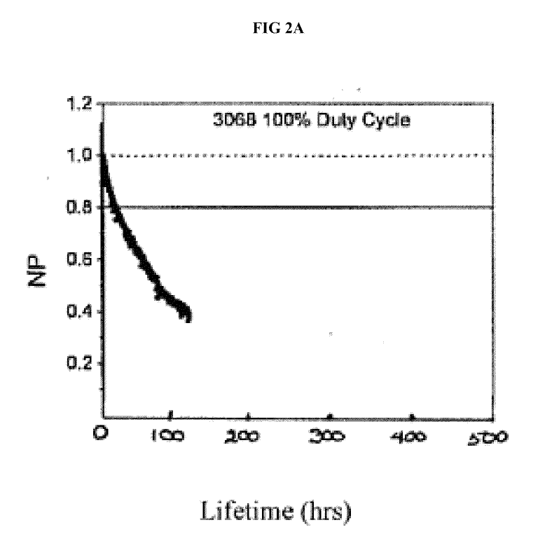

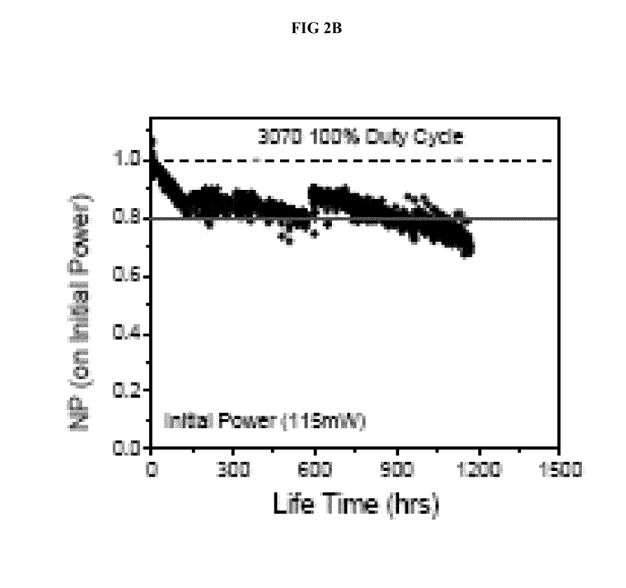

The lifetimes of devices including an IML comprising BPhen or BCP doped with lithium, prepared as described in Example 1 above, were tested under a Xe-arc lamp with about 1 sun and 100% duty cycle in ambient conditions. A Xenon lamp (Atlas Specialty Lighting, PE240E-13FM) was used to generate both the temperature and light. The output designation of ‘1Suns’ is derived from adjusting the intensity of light falling on the devices to be such that a KG-5 cell placed in the same fixture would generate the same current it generates under standard AM 1.5G testing. The devices were connected to a data acquisition setup where an adjustable DC load maintained them at their maximum power point (“MPP”). The power output of the cells was continuously monitored over time. In addition, intermittent monitoring of the PV parameters such as Voc, FF, Jsc was also performed. The temperature of devices was controlled by attaching devices onto a cooling stage with cooling water (12° C.) circulating. The intensity of Xe lamp was monitored by a Si photodiode and used to normalize the power output of the devices. Data for a device including a 5 nm IML of BPhen doped with Li (10%) were collected using the maxima power point (“MPP”) method and are shown in FIGS. 2A and 2B. As FIGS. 2A and 2B demonstrate, the decay of output power of the device including a 5 nm IML of BPhen doped with Li (10%) is markedly slower than that of a device with no IML between the active layer and the cathode. Specifically, the “burn-in” decay—defined as the exponential reduction of initial power—is significantly less for devices with the IML than it is for the control device that does not have an IML. This improvement in “burn-in” range significantly impacts the overall device lifetime which is defined as the reduction of device power to 80% of the initial power (“T80”).

### Example 4

### Fabrication of OPV Devices Comprising Various Active Layers and IML

For each experimental run, OPV devices of types A, B, and C, were prepared. The general architecture for the various OPV devices was as follows:
Substrate/ITO/PEDOT:PSS/Active Layer/IML/A1
   Specific Active Layers and OSs used in each OPV device, types A, B, and C, are described below.
   Devices A1-A11: Eleven OPV devices of the following general architecture were prepared:
Substrate/ITO/PEDOT:PSS/PV 1000/IML/A1
For each OPV device run, A1-A11, a different IML was used, as reflected in Table 2.

TABLE 2
Device A, B, and C IMLs

| | Cathode |
|---|---|
| Run# | Modification/OS |
| 1 | 10 nm Ca |
| 2 | 10 nm Yb |
| 3 | 10 nm BPhen |
| 4 | 5 nm TPBI |
| 5 | 10 nm BPhen: Yb (17%) |
| 6 | 15 nm BPhen: Yb (17%) |
| 7 | 10 nm TPBI: Yb (17%) |
| 8 | 10 nm BPhen: Yb (25%) |
| 9 | 15 nm TPBI: Yb (25%) |
| 10 | 10 nm BPhen: Yb (40%) |
| 11 | 10 nm BPhen: Li (3%) |

Devices B1-B11: Eleven OPV devices of the following general architecture were prepared:
Substrate/ITO/PEDOT:PSS/PV2000/IML/A1
For each OPV device run, B1-B11, a different OS was used, as reflected in Table 2 above.

Devices C2-C11: Ten OPV devices of the following general architecture were prepared:
Substrate/ITO/PEDOT:PSS/PV 2000/IML/A1
For each OPV device run, C2-C11, a different IML was used, as reflected in Table 2 above.

OPVs were prepared using the following procedure: The OPV devices described herein were fabricated on indium tin oxide (“ITO”) surfaces deposited on glass substrates. The ITO surface was pre-patterned to define the pixel area of 0.09 cm². The device substrates were cleaned by ultrasonication in a dilute soap solution for 20 minutes each followed by distilled water washes. This was followed by ultrasonication in isopropanol for 20 minutes and then ultrasonication in acetone for 20 minutes. The substrates were dried under nitrogen flow, after which they were treated in a UV-Ozone chamber operating at 300 W for 20 minutes.

The cleaned substrates were then spin coated with PEDOT:PSS (Baytron 4083) at 6000 rpm in a clean-room hood to a thickness of about 40 nm. The substrates were then baked at 175° C. for 30 minutes in a glove box with a nitrogen atmosphere. The coating process was done on a spin coater but can be similarly achieved with spray coating, slot die coating, ink-jetting, contact printing or any other deposition method capable of resulting in an HTL film of the desired thickness. The substrates were then coated with an Active Layer.

OPV devices made with PV 1000, A1-A11, were spin coated (350 rpm) to a thickness of about 230 nm in a clean-room glove box for 6-10 minutes. For OPV devices made with PV 2000, B1-B11, the ink was spin coated (350 rpm) to a thickness of about 210 nm in a clean-room glove box for 6-10 minutes. For OPV devices including PV 2000, C2-C11, the ink was spin coated (300 rpm) to a thickness of about 220 nm in a clean-room glove box for 6-10 minutes. The foil was changed after spinning a few substrates in order to remove excess solvent from the spin coater so that the films were spin coated in a limited amount of solvent vapor. The films were then annealed at 175° C. for 30 minutes in a glove box with a nitrogen atmosphere and were allowed to cool slowly on a hot plate to below 120° C. The samples were loaded in an evaporator (Edwards) for overnight pumping to ˜7×10⁻⁷ mbar.

Next, the samples were coated with the various IML materials, listed in Table 2 above, by physical vapor deposition. For example, in Run 5, BPhen was co-evaporated with Yb in the ratio of 83% BPhen (0.1 nm/sec) to 17% Yb (0.02 nm/sec) at a base pressure of 7×10⁻⁷ mbar, to a thickness of 10 nm. Following deposition of the IML, the cathode layer, a 200 nm layer of Al (0.4 nm/sec) with the base pressure at 5×10⁻⁷ Torr, was deposited.

The devices thus obtained were encapsulated with a glass cover slip to prevent exposure to ambient conditions by means of a UV-light curing epoxy resin cured at 80 W/cm² UV exposure for 4 minutes.

### Example 5

### Performance Parameters for OPV Devices A, B, and C Testing

The OPVs comprised pixels on a glass substrate whose electrodes extended outside the encapsulated area of the device which contain the photoactive portion of the pixels. The typical area of each pixel was 0.09 cm². The photovoltaic characteristics of devices under white light exposure (Air Mass 1.5 Global Filter) were measured using a system equipped with a Keithley 2400 source meter and an Oriel 300 W Solar Simulator based on a Xe lamp with output intensity of 100 mW/cm2 (AM1.5G). A voltage was applied to the photovoltaic device which was swept from −2 V to 2 V. The resulting photocurrent was measured using the Keithley source meter and an efficiency of the device with reference to the incident light intensity was calculated. Other parameters of interest were recorded such as the short circuit current density (Jsc), the series resistance (Rs), and the fill factor (FF)—which is defined as the product of the peak voltage and peak current density (Vmax*Jmax) divided by the product of the short circuit current density and the open circuit voltage (Jsc*Voc). The light intensity was set using an NREL-certified Si-KG5 silicon photodiode.

Table 3 below shows the resulting device parameters from the devices studied.

TABLE 3
Measured OPV Device Parameters

| | Cathode | | Device | Device | Device |
|---|---|---|---|---|---|
| Run# | Modification/IML | | A | B | C |
| 1 | 10 nm Ca | Jsc | 9.5 | 8.51 | — |
| | | FF | 0.61 | 0.7 | — |
| | | Rs | 8.4 | 9.8 | — |
| | | Eff % | 3.5 | 5.46 | — |
| 2 | 10 nm Yb | Jsc | 10.62 | 8.01 | 8.51 |
| | | FF | 0.64 | 0.63 | 0.64 |
| | | Rs | — | 10.2 | 10.51 |
| | | Eff % | 4.02 | 3.92 | 4.2 |
| 3 | 10 nm BPhen | Jsc | 10.6 | 9.9 | 10.6 |
| | | FF | 0.6 | 0.66 | — |
| | | Rs | 7.3 | 10.8 | — |
| | | Eff % | 3.8 | 5.58 | — |
| 4 | 5 nm TPBI | Jsc | 11.08 | 10.42 | 8.51 |
| | | FF | 0.63 | 0.61 | 0.65 |
| | | Rs | 7.84 | 22.95 | 13.71 |
| | | Eff % | 3.94 | 4.21 | 3.57 |
| 5 | 10 nm BPhen: Yb (17%) | Jsc | 10.7 | 10.13 | 9.46 |
| | | FF | 0.63 | 0.74 | 0.74 |
| | | Rs | 6.21 | 7.32 | 7.23 |
| | | Eff % | 4.05 | 6.24 | 5.94 |
| 6 | 15 nm BPhen: Yb (17%) | Jsc | 10.55 | 10.3 | 10.51 |
| | | FF | 0.68 | 0.73 | 0.71 |
| | | Rs | 5.71 | 8.47 | 8.35 |
| | | Eff % | 4.34 | 6.33 | 6.35 |
| 7 | 10 nm TPBI: Yb (17%) | Jsc | 10.55 | 9.83 | 10.32 |
| | | FF | 0.67 | 0.71 | 0.72 |
| | | Rs | 7.5 | 10 | 9.25 |
| | | Eff % | 4.23 | 5.96 | 6.27 |
| 8 | 10 nm BPhen: Yb (25%) | Jsc | 10.8 | 10.05 | 9.58 |
| | | FF | 0.64 | 0.71 | 0.68 |
| | | Rs | 5.81 | 6.8 | 9.24 |
| | | Eff % | 4.22 | 6.09 | 5.46 |
| 9 | 15 nm TPBI: Yb (25%) | Jsc | 10.55 | 10.3 | 10.51 |
| | | FF | 0.68 | 0.73 | 0.71 |
| | | Rs | 5.71 | 8.47 | 8.35 |
| | | Eff % | 4.34 | 6.33 | 6.35 |
| 10 | 10 nm BPhen: Yb (40%) | Jsc | 10.15 | 10.11 | 10.55 |
| | | FF | 0.58 | 0.74 | 0.73 |
| | | Rs | 7.8 | 7.4 | 7.41 |
| | | Eff % | 3.56 | 6.33 | 6.48 |
| 11 | 10 nm BPhen: Li (3%) | Jsc | 10.94 | 10.09 | 10.25 |
| | | FF | 0.66 | 0.69 | 0.64 |
| | | Rs | 5.6 | 8.57 | 8.45 |
| | | Eff % | 4.32 | 5.83 | 5.31 |

Jsc: Short circuit current (mA/cm²)
FF: Fill factor
Rs: Series resistance (Ω/cm²)
Eff %: Efficiency %

### Example 6

### Fabrication of OPV Modules

A first set of OPV modules (FIG. 8) was fabricated on glass substrates coated with Cr/Ni/Cr reinforced indium tin oxide (“ITO”) having approximately 8-10 Ω/□ sheet resistance. The devices contained 54 individual pixels that were arranged in 6 columns and 9 rows on a 6 inch×6 inch glass substrate. The area of each individual pixel was 10×20 mm. The nine pixels in a column were connected in series and the six columns were connected in parallel. The device substrates were cleaned by ultrasonication in a dilute detergent solution for 15 minutes followed by distilled water washes. The substrates were dried under nitrogen flow and then treated in a UV-Ozone chamber operating at 300 W for 10 minutes.

The cleaned substrates were then spin coated with Plexcore hole transport layer (HTL) at 1000 rpm in a clean-room hood to a thickness of about 60 nm. Note that other methods can be used such as, for example, spray coating, ink jetting, contact printing, and other methods. The substrates were then baked at 175° C. for 30 minutes in air. The substrates were then spin-coated with an Active Layer.

The active layer (PV 2000 series slot die coating ink) was deposited using an FAS slot die coater in air. The target active layer thickness was 200 nm. After active layer coating, the substrates were transferred into a glove box under nitrogen and annealed on a hot plate at 175° C. for 30 minutes.

After the HTL and active layers were deposited, the individual cells of the module were electrically isolated from each other by ablating off the organic material using an excimer laser. This laser patterning also opened up contacts for the interconnects for the electrical connections of the columns and rows. After the laser ablation step, the samples were transferred to an evaporator for cathode deposition.

In the vacuum deposition step, the samples were coated with either a BPhen:Yb/Al cathode or a Ca/Al bilayer cathode. The Bphen:Yb layer was an IML of BPhen and Yb, co-deposited to create the desired composition of the OS layer. Yb deposition rates were 0.1, 0.3, or 0.5 Å/s. Ratios of Bphen to Yb deposition rates were 1, 5, or 15. The thickness of the BPhen/Yb layers ranged from 5-35 nm. The Al deposition rate was 0.5 nm/sec. The Ca/Al electrodes were deposited at rates of 0.2 nm/sec to 20 nm and 0.5 nm/sec to 80 nm for Ca and Al respectively. All depositions occur at base pressures of 7.5×10⁻⁷ mtorr.

These modules were then encapsulated using an MBraun UV press with a glass cover slip, Saes Dynic getters, and epoxy resin. Up to 20 Saes Dynic getters were placed around the perimeter of the module for encapsulation. The perimeter of a glass cover slip was coated with epoxy resin and pressed onto the glass substrate where it was cured by means of a UV-light at 80 W/cm² UV exposure for 80 seconds.

Stripe modules were also prepared using these methods but a different substrate. The substrate comprised ten equal sized rectangular ITO stripes on a glass substrate leading to an active area on the device of 98 cm² (relatively more active area, higher aperture).

### Example 7

### Module Evaluation

Photovoltaic characteristics of the modules prepared in Example 6 under white light exposure (Air Mass 1.5 Global Filter) were measured using a system equipped with a Keithley 2400 source meter and an Oriel 300 W Solar Simulator based on a Xe lamp with output intensity of 100 mW/cm2 (AM1.5G). A voltage was applied to the photovoltaic module which was swept from −10 V to 10 V. The resulting photocurrent was measured using the Keithley source meter and an efficiency of the device with reference to the incident light intensity (PCE) was calculated. Other parameters of interest were recorded such as the short circuit current density (Jsc), the series resistance (Rs), and the fill factor (FF)—which is defined as the product of the peak voltage and peak current density (Vmax*Jmax) divided by the product of the short circuit current density and the open circuit voltage (Jsc*Voc). The light intensity was set using an NREL-certified Si-KG5 silicon photodiode. These results are summarized in Table 4 (PV2000 series slot die ink system).

TABLE 4
Measured OPV Parameters for Modules of Example 6

| | Thickness of | Ratio of | Yb | | Avg | | Avg |
|---|---|---|---|---|---|---|---|
| | BPhen/Yb | Deposition Rates | Deposition | Avg Jsc | Voc | Avg | PCE |
| Device | Layer (nm) | for BPhen/Yb | Rate (\acute{Å}/s) | (mA/cm²) | (V) | FF | (%) |
| 1 | 5 | 5 | 0.1 | 0.91 | 6.7 | 0.58 | 3.49 |
| 2 | 5 | 5 | 0.5 | 0.93 | 6.3 | 0.56 | 3.25 |
| 3 | 5 | 15 | 0.1 | 0.84 | 6.8 | 0.57 | 3.19 |
| 4 | 5 | 15 | 0.5 | 0.92 | 6.4 | 0.57 | 3.29 |
| 5 | 35 | 5 | 0.1 | 0.8 | 6.8 | 0.55 | 3.0 |
| 6 | 35 | 5 | 0.5 | 0.85 | 6.5 | 0.57 | 3.14 |
| 7 | 35 | 15 | 0.1 | 0.84 | 6.9 | 0.59 | 3.39 |
| 8 | 35 | 15 | 0.5 | 0.88 | 6.0 | 0.57 | 3.01 |
| 9 | 20 | 10 | 0.3 | 0.89 | 6.6 | 0.58 | 3.39 |

### Example 8

### Module Preparation and Stability Testing

Modules were fabricated using the method as described in Example 6. Module active layers contained PV1000 or PV2000. Module IMLs contained Ca, Li:BPhen, Yb:BPhen, or Yb:TPBI.

Stability of the modules was evaluated under two different conditions. The first (“Xe”) was ambient temperature and humidity, subject to continuous exposure to a “1 Sun” intensity Xenon lamp. The second (“QSun”) was 85° C. temperature and 85% relative humidity, subject to continuous exposure to a “0.4 Sun” intensity Xenon lamp.

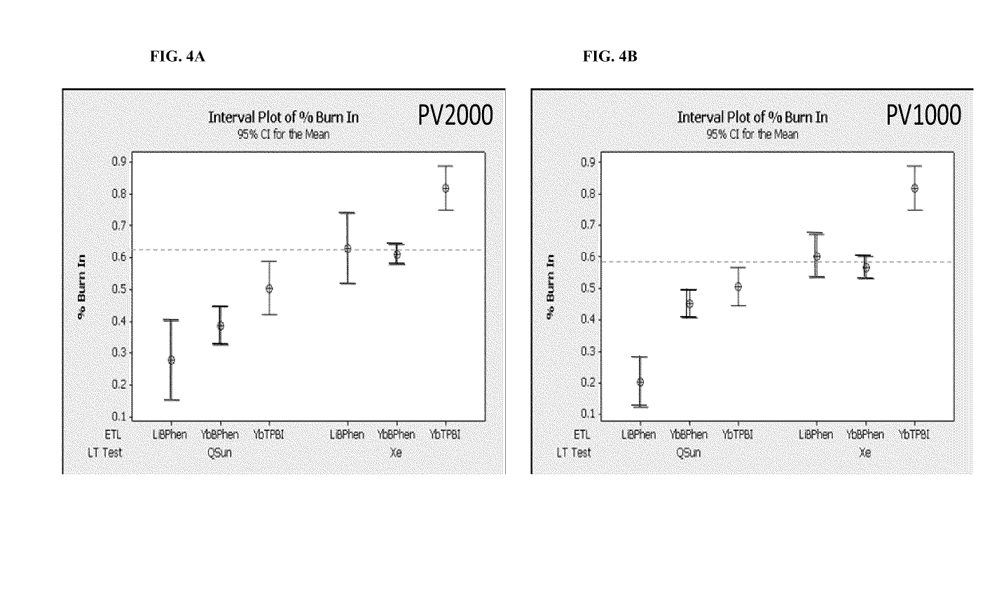

FIG. 4 shows burn-in for modules subjected to the two testing conditions, broken down by active layer and OS layer compositions. Burn-in is the ratio of a module's measured efficiency after 200 hours of testing relative to the initial measured efficiency. The Yb:TPBI IML appears to provide better burn-in than the Li:BPhen OS layer, regardless of environmental conditions or the active layer ink. Burn in of over 50%, of over 60%, of over 70%, or of over 80% can be achieved.

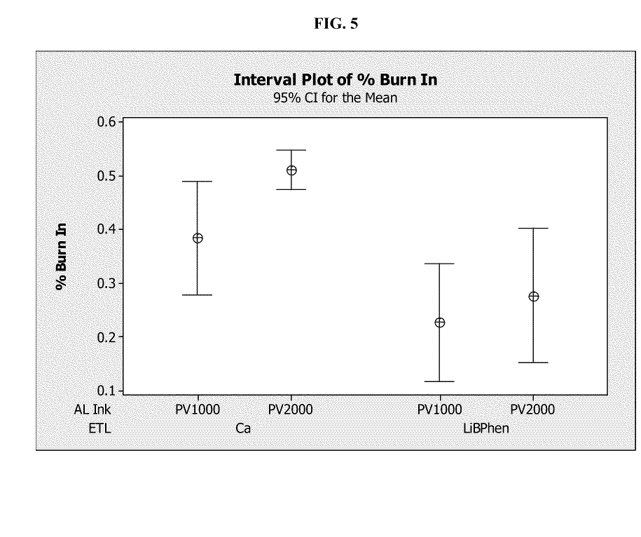

FIG. 5 shows modules subjected to the “QSun” testing conditions, where the IML comprises Ca or Li:BPhen and the active layer comprises PV1000 or PV2000.

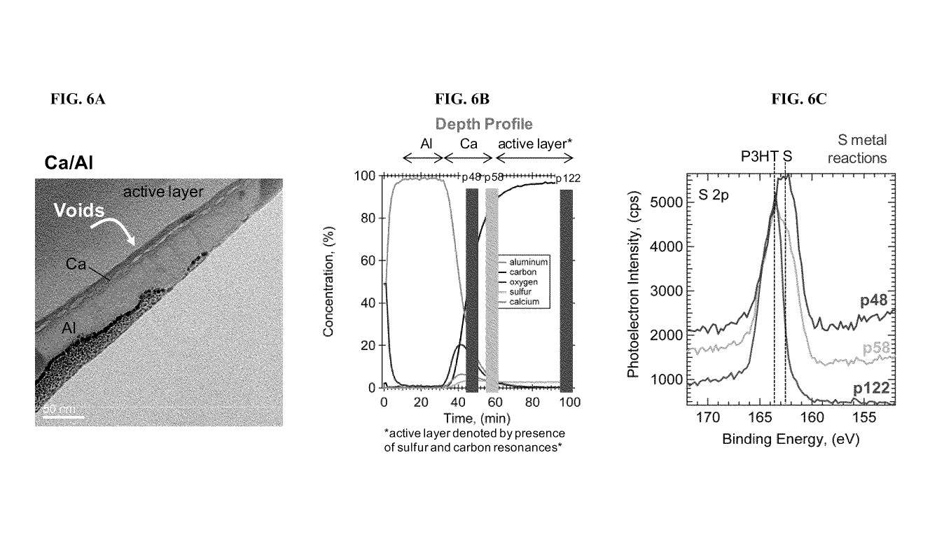

FIG. 6A shows a cross sectional transmission electron microscopy image of a module's active layer, a Ca interfacial layer, and an Al layer, taken before environmental testing. The Ca layer shows voids consistent with oxidation at the Ca—Al interface. FIG. 6B shows the XPS depth profile of the module of FIG. 6A. In this case, poly-3-hexylthiophene (P3HT) was the active layer polymer. It can be seen from the high resolution XPS spectra of sulfur 2p region that the sulfur moieties in the P3HT polymer also undergo reaction as a result of the Ca layer deposition. In the FIG. 6C, it can be seen that closest to the Ca layer, the sulfur moieties in the P3HT polymers are reduced to sulfide species (blue spectrum, p48) whereas at depths further away from the Ca layer (orange, red spectra, p58 and p122), fewer amounts of sulfides species are observed (orange spectrum, p58) until a depth is reached such that no reactions with the Ca layer are observed and only intrinsic sulfur signals consistent with intrinsic P3HT are observed (red spectrum, p122.).

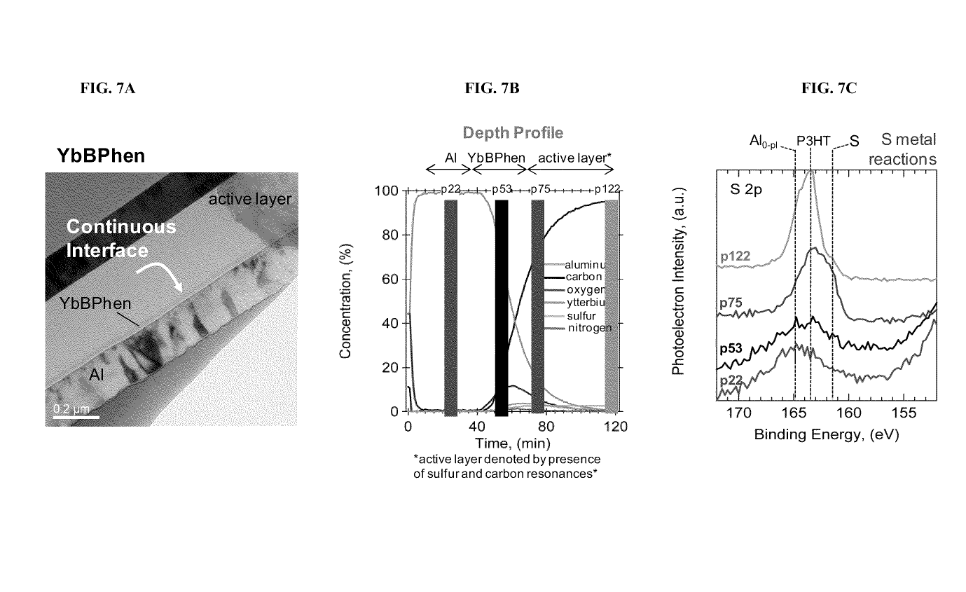

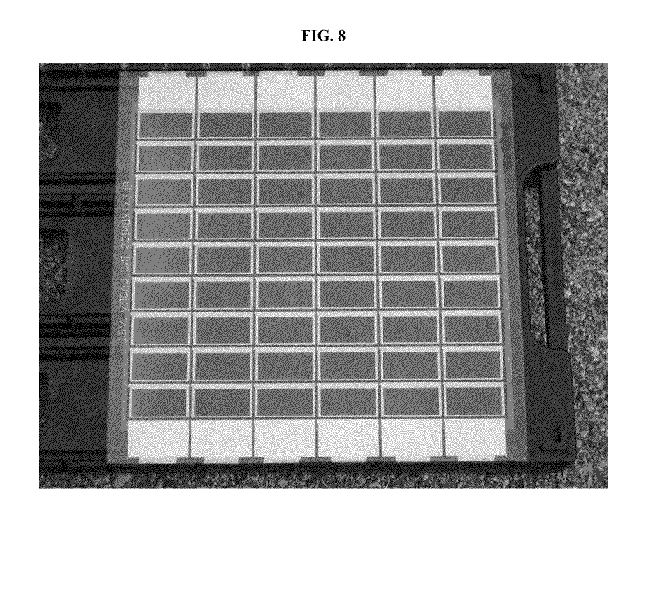

FIG. 7A-7C show the contrasting results for a module that has a Yb:BPhen interfacial layer. FIG. 7A shows a smooth continuous Yb:BPhen interfacial layer, with none of the oxidation-based voids that had been seen in the Ca layer of FIG. 6A. FIG. 7B shows that some interfacial oxidation occurred, but not as severe as that shown in FIG. 6B. The relevant peaks are much smaller. FIG. 7C shows that less reduction of the P3HT sulfurs has occurred, with no formation of a separate sulfide layer (p122 is green; p75 is blue; p53 is black; and p22 is red).

### Example 9

### Effect of Ramp-Up Time

The processes and instrumentations were adapted to provide better deposition, better reproducibility, and more stable rates of deposition. In particular, ramp up process of at least, for example, 30 minutes for deposition rates for the IML in the vacuum system were found to improve performance. This may in some embodiment result in a “baking out” of species like water and oxygen.

1. A device comprising:
at least one anode;
at least one organic photovoltaic device active layer disposed on the anode, wherein the active layer comprises at least one p-type material and one n-type material;
at least one interfacial modification layer disposed on the active layer, wherein the interfacial modification layer comprises at least one dopant and at least one organic semiconductor; and
at least one cathode disposed on the interfacial modification layer,
wherein the dopant and the active layer are adapted to provide the device with a power conversion efficiency of at least 4%.

2. The device of claim 1, further comprising a substrate, wherein the substrate is transparent.

3. The device of claim 1, wherein the anode comprises a transparent conductor.

4. The device of claim 1, further comprising a hole transport layer between the anode and the active layer.

5. The device of claim 1, wherein the p-type material comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, or mixtures thereof.

6. The device of claim 1, wherein the n-type material is selected from the group consisting of [6,6]-phenyl-C₆₁-butyric acid methyl ester (PCBM) and indenyl-substituted fullerenes.

7. The device of claim 1, wherein the dopant comprises a metal.

8. The device of claim 1, wherein the interfacial modification layer comprises ytterbium and BPhen, or ytterbium and TPBI.

9. The device of claim 1, wherein the cathode comprises aluminum.

10. The device of claim 1, further comprising a hole transport layer and a transparent substrate, the anode comprises indium tin oxide, the active layer comprises indenyl-derivitized fullerene, the interfacial modification layer comprises BPhen and ytterbium, or TPBI and ytterbium, and the cathode comprises aluminum.

11. A device comprising:
at least one anode,
at least one organic photovoltaic device active layer disposed on the anode, wherein the active layer comprises at least one conjugated polymer and at least one fullerene, wherein the fullerene comprises an indenyl-substituted fullerene, at least one interfacial modification layer disposed on the active layer, wherein the interfacial modification layer comprises at least one metal, which is an inner transition metal, and at least one organic semiconductor, and
at least one cathode disposed on the interfacial modification layer.

12. The device of claim 11, wherein the anode comprises a transparent conductor.

13. The device of claim 11, further comprising a hole transport layer between the anode and the active layer.

14. The device of claim 11, wherein the fullerene is selected from the group consisting of [6,6]-phenyl-C₆₁-butyric acid methyl ester (PCBM) and indenyl-substituted fullerenes.

15. The device of claim 11, wherein the interfacial modification layer metal comprises ytterbium.

16. The device of claim 11, wherein the interfacial modification layer comprises ytterbium and BPhen, or ytterbium and TPBI.

17. The device of claim 11, wherein the interfacial modification layer is about 1 nm to about 30 nm thick.

18. The device of claim 11, wherein the active layer is about 150 nm to about 250 nm thick.

19. The device of claim 11, further comprising a hole transport layer and a transparent substrate, the anode comprises indium tin oxide, the active layer comprises P3HT and indenyl-substituted fullerene, the interfacial modification layer comprises BPhen and ytterbium, or TPBI and ytterbium, and the cathode comprises aluminum.

20. The device of claim 11, wherein the interfacial modification layer organic semiconductor has a HOMO value lower in energy than the HOMO value of the active layer conjugated polymer.

21. A device comprising:
at least one anode,
at least one organic photovoltaic device active layer disposed on the anode, wherein the active layer comprises at least one p-type material and at least one n-type material,
at least one interfacial modification layer disposed on the active layer, wherein the interfacial modification layer comprises at least one dopant and at least one organic semiconductor, and
at least one cathode disposed on the interfacial modification layer,
wherein the dopant and the active layer are adapted to provide the device with a lifetime that is at least about 25% longer than an analogous device that does not contain the interfacial modification layer.

22. The device of claim 21, wherein the anode comprises indium tin oxide, SnO, ZnO, or NiO₍ₓ₎.TiO₂.

23. The device of claim 21, further comprising a hole transport layer between the anode and the active layer.

24. The device of claim 21, wherein the p-type material and n-type material of the active layer are present in a ratio of from about 1 n-type to about 1 to about 2 p-type, based on weight.

25. The device of claim 21, wherein the dopant comprises a metal.

26. The device of claim 21, wherein the dopant is selected from the group consisting of alkali metals, alkali earth metals, transition metals, rare earth metals, and metal oxides.

27. The device of claim 21, wherein the dopant is selected from the group consisting of cesium, barium, magnesium, molybdenum oxide, tungsten oxide, chromium, silver, gold, lithium, calcium, and ytterbium.

28. The device of claim 21, wherein the dopant comprises an organic material.

29. The device of claim 21, wherein the organic semiconductor is selected from the group consisting of TPBI, Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups.

30. The device of claim 21, wherein the interfacial modification layer comprises ytterbium and BPhen, or ytterbium and TPBI.

31. A device comprising:
at least one anode;
at least one organic photovoltaic device active layer disposed on the anode, wherein the active layer comprises at least one p-type material and one n-type material;
at least one interfacial modification layer disposed on the active layer, wherein the interfacial modification layer comprises at least one dopant and at least one organic semiconductor; and
at least one cathode disposed on the interfacial modification layer,
wherein the dopant and the active layer are adapted to provide the device with a normalized power output greater that about 80% of initial power for at least about 25 hours.

32. The device of claim 31, further comprising a hole transport layer between the anode and the active layer.

33. The device of claim 31, wherein the p-type material comprises poly (3-hexylthiophene-2,5-diyl) (P3HT), polyphenylene vinylene (PPV), substituted polythiophenes, substituted polycarbazoles, copolymer comprising at least one dithieno[3,2-b:2′,3′-d]pyrrole (DTP) repeat unit, a donor-acceptor polymer, or mixtures thereof.

34. The device of claim 31, wherein the n-type material is selected from the group consisting of [6,6]-phenyl-C₆₁-butyric acid methyl ester (PCBM) and indenyl-substituted fullerenes.

35. The device of claim 31, wherein the p-type material comprises P3HT and the n-type material is selected from the group consisting of PCBM and indenyl-substituted fullerenes.

36. The device of claim 31, wherein the p-type material and n-type material of the active layer are present in a ratio of from about 1 n-type to about 1 to about 2 p-type, based on weight.

37. The device of claim 31, wherein the dopant comprises a metal.

38. The device of claim 31, wherein the dopant is selected from the group consisting of alkali metals, alkali earth metals, transition metals, rare earth metals, and metal oxides.

39. The device of claim 31, wherein the dopant is selected from the group consisting of cesium, barium, magnesium, molybdenum oxide, tungsten oxide, chromium, silver, gold, lithium, calcium, and ytterbium.

40. The device of claim 31, wherein the organic semiconductor is selected from the group consisting of TPBI, Bathophenanthroline(4,7-Diphenyl-1,10-phenanthroline) (“BPhen”), 2,9-dimethyl-4,7-diphenyl-1,10-phenantrolene (“BCP”), Tris-(8-hydroxyquinolino)aluminum (“Alq3”), 4,4′-Bis(carbazol-9-yl)-biphenyl (“CBP”), Bis-(2-methyl-8-quinolinolato)-4-(phenylphenolato)-aluminum-(III) (“BAlq”), TPBI, 4,4′,4″-Tris(carbazol-9-yl)-triphenylamine (“TCTA”), 2-Phenyl-5-(4-biphenyl)-1,3,4-oxadiazole (“PBD”), 2,2′-(1,3-Phenylene)bis[5-[4-(1,1-dimethylethyl)phenyl]]-1,3,4-Oxadiazole (“OXD-7”), N,N′-Bis(naphthalen-1-yl)-N,N′-bis(phenyl)-benzidine (“NPB”(“a-NPD”)), lithium quinoline (“Liq”), Ir(piq)3, mCP, TPOB, 3,5-Bis(4-tert-butyl-phenyl)-4-phenyl-triazole (“TAZ”), TPQ, TRZ2, TRZ3, TRZ4, TPhB, TPPhB, TTPhB, TTPhPhB, and thiophene-based molecules capped with two dimesitylboryl groups.

41-53. (canceled)

54. A module comprising at least one device of claim 1.

55. A module comprising at least one device of claim 11.

56. A module comprising at least one device of claim 21.

57. A module comprising at least one device of claim 31.

58. (canceled)
